(19) United States
(12) Patent Application Publication
(10) Pub. No.: US 2008/0023763 A1
(43) Pub. Date: Jan. 31, 2008

(54) Threshold-voltage trimming of insulated-gate power devices

(76) Inventor: Richard A. Blanchard, Los Altos, CA (US)

Correspondence Address: GROOVER & Associates, BOX 802889, DALLAS, TX, 75380-2889, US

(21) Appl. No.: 11/880,484

(22) Filed: Jul. 19, 2007

Related U.S. Application Data
(60) Provisional application No. 60/832,044, filed on Jul. 19, 2006.

(51) Int. Cl. H01L 29/78; H01L 21/336

(52) U.S. Cl. 257/339; 257/406; 438/288; 257/E29.256; 257/E21.417

(57) ABSTRACT

Methods and systems for precision manufacture of MOS-gated power devices. The raw device includes a stratum of semiconductor nanocrystals embedded at or near the top edge of the gate dielectric, and after the device has been built a programmation operation trims the device to the precisely correct threshold voltage, by charging this stratum.

### CROSS-REFERENCE TO OTHER APPLICATION

Priority is claimed from provisional application 60/832044 filed on Jul. 19, 2006, which is hereby incorporated by reference.

### BACKGROUND OF THE INVENTIONS

The present application relates to field-effect-gated power and analog devices, to methods for manufacturing them, and to systems and methods which incorporate these.

Note that the points discussed below may reflect the hindsight gained from the disclosed inventions, and are not necessarily admitted to be prior art.

Many types of power devices are “MOS-gated,” i.e. use some form of field-effect transistor action merged with other device types. For example, the classic n-channel DMOS transistor has a heavily doped source region (e.g. n+) which is self-aligned to a channel region (e.g. p-type) and to a deep body region (also p-type, but deeper than the source diffusion and having less lateral outdiffusion than the p-type channel diffusion). A gate electrode is capacitively coupled to the channel region, to control current flow. Electrons passing through the channel region then pass through a drift region, where most of the voltage drop appears in the off state, to the drain.

One basic requirement on all “MOS-gated” devices is threshold voltage uniformity. The voltage at which a field-effect transistor begins to turn on is affected by many process variables, including for example channel doping, gate dielectric thickness, and interfacial effects, as well as many other variables. Threshold voltage uniformity is desirable to achieve better matching of parallel devices, better control of current/voltage operation (and hence less risk of breakdown), and better load balancing at turn-on. An additional objective factor is that customers are willing to pay more for tighter specifications.

One possibility to control the threshold voltage of power devices is introducing ionized dopants. For example, DMOS transistors may be fabricated by introducing an atomic species such as cesium into the gate dielectric layer prior to the deposition of the polycrystalline silicon layer that later becomes the conductive gate electrode. The species that is implanted, the dose and energy used for the implantation, the gate composition and thickness, and the thermal treatment after implantation all affects the final threshold voltage value. In the ideal case, the change is threshold voltage would be a precise and constant value. Unfortunately, process variables, including those associated with the species that is implanted to cause the threshold voltage shift, produce depletion mode transistors with a range of threshold voltage values. This range of values may be adequate for some applications, but too large for other applications.

### SUMMARY OF THE INVENTIONS

The present inventor has realized that a technique from nonvolatile memory research can be adapted to the very different requirements of power devices. By introducing semiconductor nanocrystals (or the like) into or on top of the gate dielectric layer, a stratum of charge-trapping locations is created. By injecting carriers into this stratum, the threshold voltage of the device is shifted.

This is particularly advantageous as a trimming operation. After a field-effect-gated power device is manufactured, its threshold voltage can be measured (or otherwise detected), and a programmation operation is performed to shift the threshold voltage toward its target value.

In other classes of embodiments, a similar structure and trimming can be applied to the fabrication of MOS analog devices. The device dimensions and operating voltages are very different from power devices, and yet the technique of threshold voltage trimming by programmation-type operations permits a new degree of precision to be achieved. These are very advantageous in a number of MOS analog circuit blocks, including e.g. Precision MOSFET current sources; Matched MOSFET current mirrors; D-to-A circuits based on device matching; and/or Current sources with precise temperature behavior (since the temperature dependence of the current through a MOSFET can be adjusted by changing its Vt.)

Other operations are commonly used during fabrication to adjust the expected threshold voltage; commonly a shallow implant is performed into the semiconductor channel material to do this. However, this is quite different from a trimming operation, which adjusts the threshold voltage of a particular devices individually, rather than the average threshold voltage of all devices.

Other kinds of charge-trapping structures have been proposed in the nonvolatile memory art. However, nanocrystals (and the like) have the important advantage of lateral uniformity, and reduced risk of edge effects, since almost all nanocrystals are surrounded by a substantially identical dielectric.

In a further class of embodiments, additional oxidation can be formed to avoid nanocrystal exposure at the edge of the gate stack.

In another class of embodiments, these ideas are applied to DMOS devices. Since the gate conductor and gate dielectric can be patterned, the stratum of traps can be patterned similarly. This permits the effective threshold voltage to be trimmed over the channel, without shifting the threshold voltage of parasitic devices elsewhere. Thus it is possible to fabricate the structure so that only SOME transistors have trimmable threshold voltages.

In another class of embodiments, a large power device is fabricated so that only some parts of the gate structure are trimmable. Thus, for example, the charge-trapping stratum can be avoided at the perimeter, where the risk of hot carrier generation during operation is higher. Thus stray hot electrons caused by avalanche breakdown at the perimeter will not alter the threshold voltage of gate regions far from perimeter.

The disclosed innovations, in various embodiments, provide one or more of at least the following advantages:
Better matching of parallel power devices;
Better control of the current/voltage operating point in power devices, and hence less risk of breakdown;
Power device circuits with better load balancing at turnon;
Power devices with tighter specifications (and hence higher prices);
Better MOSFET current sources;
Better Matched MOSFET current mirrors;
Better D-to-A circuits, using improved device matching; and/or
Current sources with precise temperature behavior.

### BRIEF DESCRIPTION OF THE DRAWINGS

The disclosed inventions will be described with reference to the accompanying drawings, which show important sample embodiments of the invention and which are incorporated in the specification hereof by reference, wherein:

FIG. 1 schematically shows how the as-manufactured distribution of threshold voltages is changed into a much tighter distribution of trimmed threshold voltages.

FIG. 2(a) shows an example of a procedure where the threshold voltage of a trimmable device is adjusted up or down using Fowler-Nordheim tunneling.

FIG. 2(b) shows an example of a procedure where the threshold voltage of a trimmable device is adjusted upward using channel hot electrons.

FIGS. 3a-3d show a sequence of stages in the fabrication of an n-channel DMOS device, in a sample embodiment.

### DETAILED DESCRIPTION OF THE PREFERRED EMBODIMENTS

The numerous innovative teachings of the present application will be described with particular reference to presently preferred embodiments (by way of example, and not of limitation).

The present invention disclosure describes a technique that may be used to obtain DMOS-FET's with a threshold voltage that can be “trimmed” to a precise value at final test. The “trimmed” threshold value is obtained by introducing semiconductor nanocrystals into or on top of the gate dielectric layer in addition to the implantation of the species that produces the depletion mode performance. Two common semiconductors that can be used for the nanocrystals are silicon and germanium. The semiconductor nanocrystals can be formed using CVD on top of the gate dielectric. This technique is described in Ammendola, Ancarani, Triolo, Corso, Crupi, Perniola, Gerardi, Lombardo, and DeSalvo, “Nanocrystal floating gate memories for FLASH device applications,” Workshop on Non volatile memories with discrete storage nodes, 19 Sep. 2003, Estoril, Portugal. This publication is hereby incorporated by reference in its entirety.

An alternative technique forms nanocrystals by CVD between slices of the gate dielectric layers.

Another alternative technique forms nanocrystals by implanting the semiconductors species directly into the gate dielectric layer. This technique is described in Tsoukalas, Dimitrakis, and Noramnd, “Nanocrystals and their application is nonvolatile memories,” First International Workshop on Semiconductors Nanocrystals, SEMINANO2005, Sep. 10-12, 2005, Budapest, Hungary. This publication is hereby incorporated by reference in its entirety.

Following the gate dielectric formation step and the addition of both the species that produces the depletion-mode characteristics and the semiconductors nanocrystals, the remainder of the DMOS fabrication sequences is completed. The “trim” step occurs during test, when the actual device characteristics are measured. The threshold voltage value is measures, and sufficient voltage is applied between the gate electrode and the combination of the source/body region and the drain region to cause carriers (either electrons or holes) to be transported from the substrate to the nanocrystals. The threshold voltage values is measures, and sufficient voltage is applied between the gate electrode and the combination of the source/body region and the drain region to cause carriers (either electrons or holes) to be transported from the semiconductor substrate through the gate dielectric layer to the semiconductor nanocrystals. The charge that comes to rest on the silicon nanocrystals changes the threshold voltage.

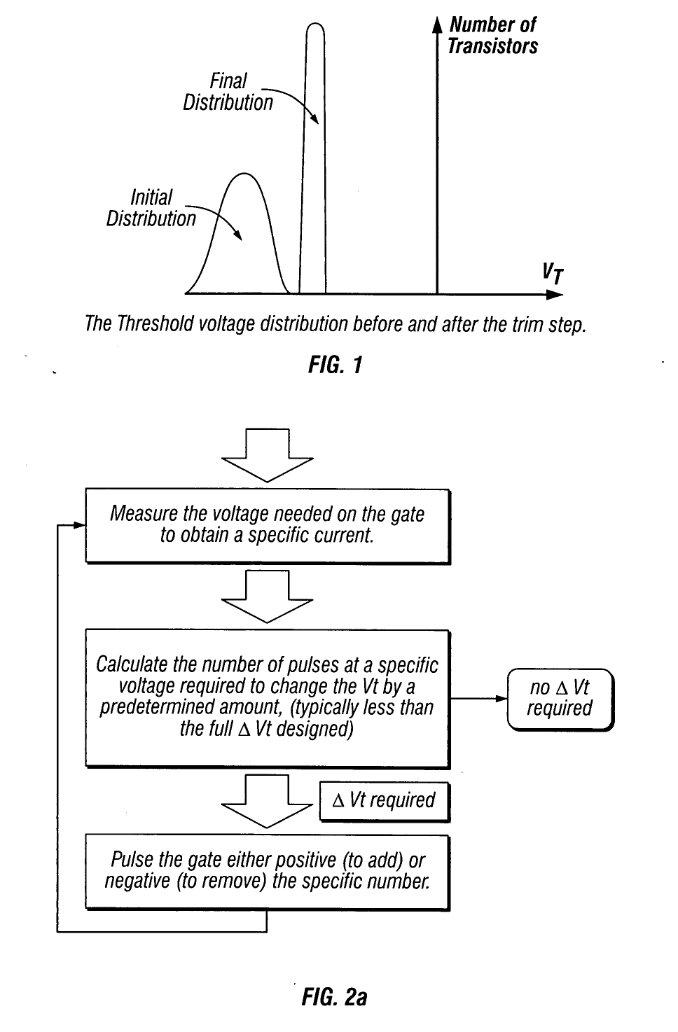

Following is a quantitative example of the shifts which are expected: if devices for 400V operation are manufactured with a Vt spread of 2000 mV, we include a nanocrystal layer of 20 nm thick which we can program with a differential area charge of up to 1×10¹²/cm⁻², to get a net controllable Vt shift of 0.5 to 5V, depending on the gate oxide thickness (e.g. in the range of 20-100 nm). Thus after the devices are manufactured, the stratum of nanocrystals (or the like) can be programmed to achieve several Volts of change in threshold voltage. Thus all the devices, which may have started out with a broad distribution as shown in the left-hand curve of FIG. 1, are converged to a narrower distribution, as schematically shown in the right-hand curve of FIG. 1.

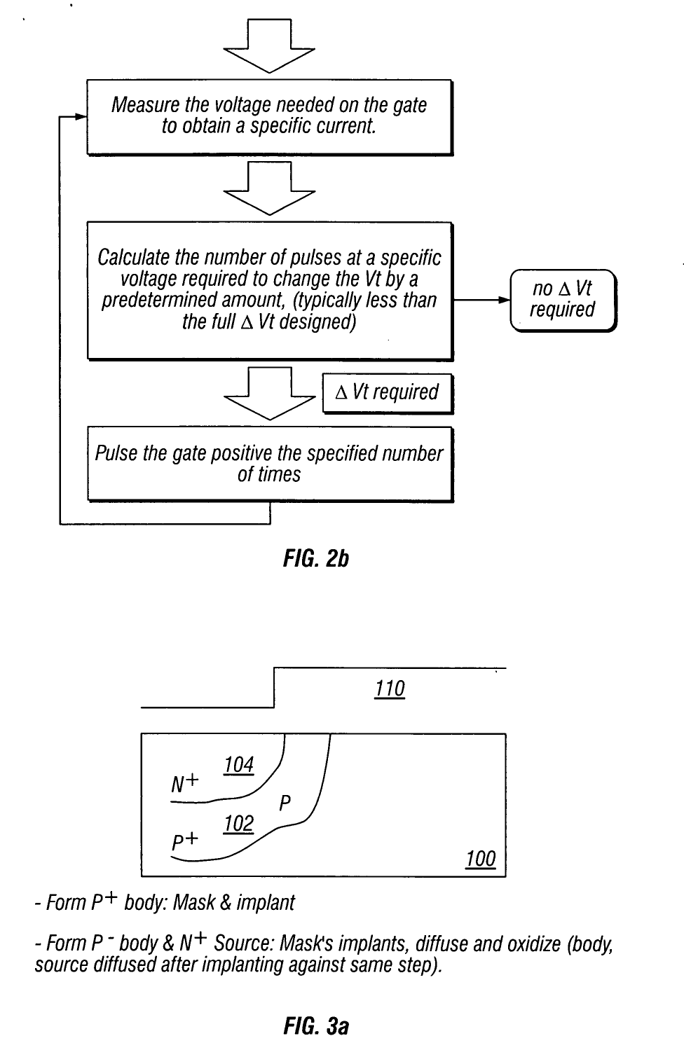

FIG. 2(a) shows an example of a procedure where the threshold voltage of a trimmable device is adjusted up or down using Fowler-Nordheim tunneling. In one example, the gate voltage at a given current is first measured, and this gives an indication of how far off spec the device's threshold voltage is (or is not). Next, if a shift in threshold voltage ΔVt is required, an estimated number of pulses of a given programmation voltage is calculated. (This can be done by lookup, since several heuristic factors are involved.) The gate is then pulsed positive or negative the required number of times. When no more change in Vt is required, the process is done.

FIG. 2(b) shows an example of a procedure where the threshold voltage of a trimmable device is adjusted upward using channel hot electrons. This procedure is generally similar to that of FIG. 2(a), except the threshold voltage can only be adjusted in one direction.

Note that the procedures of FIG. 2a or 2b will cause the distribution of threshold voltages to converge, as shown in FIG. 1. However, the distribution of trapped charge density will diverge, since the (area) density of trapped charge must vary enough to compensate all the variation in the left-hand curve of FIG. 1.

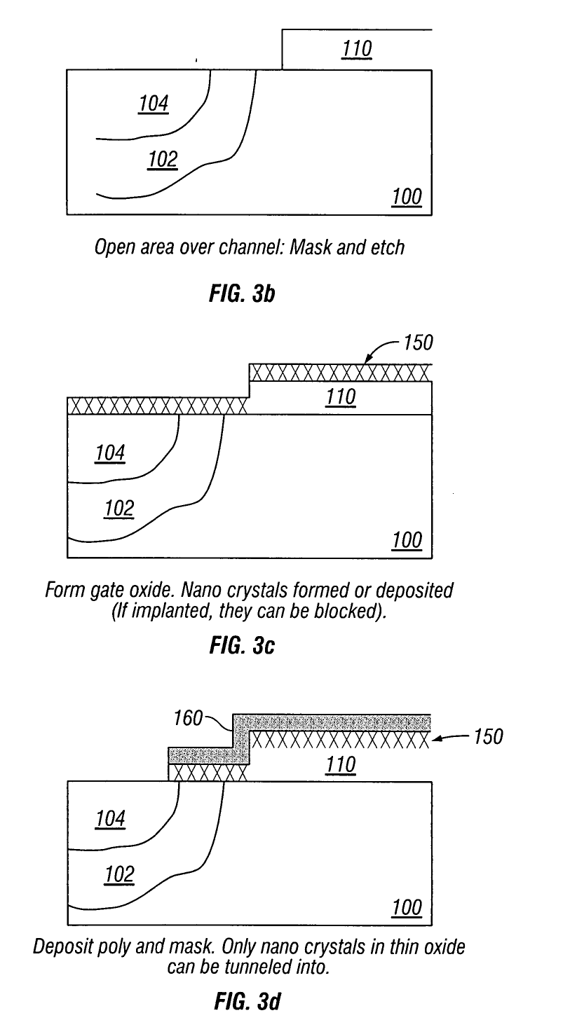

FIGS. 3a-3d show a sequence of stages in the fabrication of an n-channel DMOS device, in a sample embodiment. In a semiconductor substrate 100, a dielectric layer 110 is patterned to define areas where source locations are desired. The P+ deep body, the N+ source, and the P-shallow body (which includes channel 102) are formed in a mutually self-aligned pattern. This forms the structure of FIG. 3a; note that the p-type region which includes the channel 102 shows a double curve, because it includes both the deep-body implant and the shallow-body implant.

Next the area over desired source and channel locations is opened up, to produce the structure shown in FIG. 3b.

Next a thinner layer of dielectric 150 is formed, and semiconductor nanocrystals are formed in it (e.g. by low-energy implantation). This produces the structure of FIG. 3c.

Next a polysilicon layer 160 is deposited and etched. The etch sequence used removes the layer 150 wherever it is not covered. This produces a gate stack, over the channel region 102, in which the layer 150 provides a stratum of charge-trapping locations as describe above.

As is well known to those of ordinary skill, other steps are needed to complete fabrication of the device. After fabrication is completed, trimming operations are then performed as described above.

According to various disclosed embodiments, there is provided: a method for fabricating insulated-gate-controlled power devices, comprising the actions of: forming a gate structure which includes a gate conductor which is capacitively coupled to a semiconducting channel through a gate insulator, and which also includes a stratum of mutually isolated conductive particles at or near the interface between said gate structure and said gate insulator; and adjusting the threshold voltage of said gate structure, to meet a desired target, by injecting carriers into said stratum; whereby said carriers are trapped at said particles of said stratum to provide a permanent shift in threshold voltage.

According to various disclosed embodiments, there is provided: 9. An insulated-gate-controlled power device, comprising: a gate structure which includes a conductive gate which is capacitively coupled to a semiconducting channel through a gate insulator; wherein said gate structure also includes a stratum of mutually isolated conductive particles at or near the interface between said gate structure and said gate insulator; and wherein said conductive particles hold trapped charge.

According to various disclosed embodiments, there is provided: a plurality of insulated-gate-controlled power devices, each comprising a gate structure which includes a conductive gate which is capacitively coupled to a semiconducting channel through a gate insulator, and which also includes a stratum of mutually isolated conductive particles at or near the interface between said gate structure and said gate insulator, and wherein said conductive particles hold trapped charge; said power devices being substantially identical, EXCEPT that different ones of said devices differ more in the trapped charge of said respective strata thereof than in the threshold voltages thereof.

According to various disclosed embodiments, there is provided: Methods and systems for precision manufacture of MOS-gated power devices. The raw device includes a stratum of semiconductor nanocrystals embedded at or near the top edge of the gate dielectric, and after the device has been built a programmation operation trims the device to the precisely correct threshold voltage, by charging this stratum.

Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

For example, the disclosed trimmable gate stack can be included in a wide variety of power devices, including DMOS, VDMOS transistors, diodes, IGBTs, GTO thyristors, and a wide variety of other power devices.

For another example, the disclosed innovations are not only applicable to discrete devices, but can also be applied to trimming of one or more power devices in a smart power integrated circuit.

For another example, while the disclosed innovations are particularly advantageous in power devices, they can also be applied to analog devices.

For another example, the disclosed inventions can also be implemented with other charge-trapping strata, as long as the charge-trapping structure includes laterally isolated islands. Preferably these are semiconductor islands, but that is not strictly necessary.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

The claims as filed are intended to be as comprehensive as possible, and NO subject matter is intentionally relinquished, dedicated, or abandoned.

What is claimed is:

1. A method for fabricating insulated-gate-controlled devices, comprising the actions of:
forming a gate structure which includes a gate conductor which is capacitively coupled to a semiconducting channel through a gate insulator, and which also includes a stratum of mutually isolated conductive particles at or near the interface between said gate structure and said gate insulator; and
adjusting the threshold voltage of said gate structure, to meet a desired target, by injecting carriers into said stratum; whereby said carriers are trapped at said particles of said stratum to provide a permanent shift in threshold voltage.

2. The method of claim 1, wherein said adjusting step is preceded by a separate step of measuring the threshold voltage of the gate structure.

3. The method of claim 1, wherein said step of injecting carriers is performed by tunneling.

4. The method of claim 1, wherein said step of injecting carriers is performed using channel hot electrons.

5. The method of claim 1, wherein said fabricating step produces a threshold voltage, in substantially every device, which is less than said target; and wherein said adjusting step increases the threshold voltages of different devices by different amounts, to meet said target.

6. The method of claim 1, wherein said forming step produces multiple devices in a single integrated circuit, and said adjusting step is performed individually for multiple ones of said devices.

7. The method of claim 1, wherein said gate structure is part of a power transistor.

8. The method of claim 1, wherein said gate structure is part of a DMOS-type transistor.

9. The method of claim 1, wherein said stratum is part of said gate structure at only some locations, but not in others.

10. An insulated-gate-controlled power device, comprising:
a gate structure which includes a conductive gate which is capacitively coupled to a semiconducting channel through a gate insulator;
wherein said gate structure also includes a stratum of mutually isolated conductive particles at or near the interface between said gate structure and said gate insulator;
and wherein said conductive particles hold trapped charge.

11. The device of claim 10, comprising multiple ones of said devices in a single integrated circuit, having respectively different densities of said trapped charge.

12. The device of claim 10, wherein said gate structure is part of a power transistor.

13. The device of claim 10, wherein said gate structure is part of a DMOS-type transistor.

14. The device of claim 10, wherein said stratum is part of said gate structure at only some locations, but not in others.

15. A plurality of insulated-gate-controlled power devices,
each comprising a gate structure
which includes a conductive gate which is capacitively coupled to a semiconducting channel through a gate insulator, and
which also includes a stratum of mutually isolated conductive particles at or near the interface between said gate structure and said gate insulator,
and wherein said conductive particles hold trapped charge;
said power devices being substantially identical, EXCEPT that different ones of said devices differ more in the trapped charge of said respective strata thereof than in the threshold voltages thereof.

16. The devices of claim 15, wherein multiple ones of said devices are included in a single integrated circuit.

17. The devices of claim 15, wherein said gate structure is part of a DMOS-type transistor.

18. The devices of claim 15, wherein said stratum is part of said gate structure at only some locations, but not in others.

19. A device made by the method of claim 1.

20. An integrated circuit including devices made by the method of claim 1.
